(19) United States
(12) Patent Application Publication
(10) Pub. No.: US 2024/0038511 A1
(43) Pub. Date: Feb. 1, 2024

(54) PLASMA PROCESSING APPARATUS AND PLASMA PROCESSING METHOD

(71) Applicant: Panasonic Intellectual Property Management Co., Ltd., Osaka (JP)

(72) Inventor: Hiroshi SHIROUZU, SHIGA (JP)

(21) Appl. No.: 18/354,058

(22) Filed: Jul. 18, 2023

(30) Foreign Application Priority Data
Jul. 26, 2022 (JP) 2022-118707

(51) Int. Cl. H01J 37/32

(52) U.S. Cl. CPC H01J 37/32935; H01J 2237/334

(57) ABSTRACT

Disclosed is a plasma processing apparatus 100 including: a chamber 101 in which plasma processing is performed; an electrode part 105 configured to be applied with a high-frequency power for generating a plasma in the chamber 101; a plasma sensor 160 for measuring a measured value MV corresponding to an electric potential of the plasma; a threshold determination section 122 for determining a threshold TH, depending on a plasma processing condition; and a judgment section 123 for judging presence or absence of abnormal discharge in the chamber 101, based on the measured value MV and the threshold TH.

### CROSS REFERENCE TO RELATED APPLICATION

The present application is based on and claims priority under 35 U.S.C. § 119 with respect to the Japanese Patent Application No. 2022-118707 filed on Jul. 26, 2022, of which entire content is incorporated herein by reference into the present application.

### TECHNICAL FIELD

The present disclosure relates to a plasma processing apparatus and a plasma processing method.

### BACKGROUND OF THE INVENTION

Conventionally, a plasma processing apparatus for performing plasma processing on an object to be processed has been known as disclosed in Patent Literature 1 (JP3773189B). The plasma processing apparatus of Patent Literature 1 includes a window-type probe having a dielectric member. At the dielectric member of the window-type probe, a potential called wall potential is induced due to a plasma generated in a chamber. The plasma processing apparatus of Patent Literature 1 further includes a voltage waveform measuring unit provided at the output end of the window-type probe, and an abnormal discharge monitor mechanism for detecting an abnormal discharge of the plasma, from a change in the voltage waveform detected by the voltage waveform measuring unit.

In Patent Literature 1, that the detected voltage value exceeds a predetermined threshold is used as one of the conditions for detecting an abnormal discharge of the plasma. However, depending on various conditions such as the values of various settings in plasma processing (hereinafter, a plasma processing condition), the detected voltage value may exceed a predetermined threshold even when no abnormal discharge occurs. In other words, with conventional techniques, an abnormal discharge may fail to be detected appropriately in some cases. Under such circumstances, one of the objectives of the present disclosure is to appropriately judge the presence or absence of abnormal discharge in the chamber.

### SUMMARY OF THE INVENTION

One aspect of the present disclosure relates to a plasma processing apparatus. The plasma processing apparatus includes: a chamber in which plasma processing is performed; an electrode part configured to be applied with a high-frequency power for generating a plasma in the chamber; a plasma sensor for measuring a measured value corresponding to an electric potential of the plasma; a threshold determination section for determining a threshold, depending on a plasma processing condition; and a judgment section for judging presence or absence of abnormal discharge in the chamber, based on the measured value and the threshold.

Another aspect of the present disclosure relates to a plasma processing method. The plasma processing method includes: a plasma generation step of applying a high-frequency power to an electrode part, to generate a plasma in a chamber; a measurement step of measuring a measured value corresponding to an electric potential of the plasma; a threshold determination step of determining a threshold, depending on a plasma processing condition; and a judgment step of judging presence or absence of abnormal discharge in the chamber, based on the measured value and the threshold.

According to the present disclosure, it is possible to appropriately judge the presence or absence of abnormal discharge in the chamber.

### BRIEF DESCRIPTION OF THE DRAWINGS

FIG. 1 is a schematic cross-sectional view of one example of a plasma processing apparatus according to the present disclosure.

FIG. 2 is a schematic cross-sectional view of a plasma sensor.

FIG. 3 is a block diagram showing a configuration including a control unit of the plasma processing apparatus.

### DETAILED DESCRIPTION OF THE INVENTION

Embodiments of a plasma processing apparatus and a plasma processing method according to the present disclosure will be described below by way of examples. It is to be noted, however, that the present disclosure is not limited to the examples described below. In the description below, specific numerical values and materials are exemplified in some cases, but other numerical values and materials may be applied as long as the effects of the present disclosure can be achieved.

### Plasma Processing Apparatus

A plasma processing apparatus according to the present disclosure may be, for example, a plasma etching apparatus, a plasma cleaning apparatus, a plasma dicer, a plasma ashing apparatus, or a plasma CVD apparatus. The plasma processing apparatus according to the present disclosure includes a chamber, an electrode part, a plasma sensor, a threshold determination section, and a judgment section.

The chamber is configured to perform plasma processing in its inside. The chamber may have a horizontal base, and an openable and closable lid or shutter. For example, the lid may be opened and closed by ascending or descending motion, or may be opened and closed by rotating motion. By bringing the chamber into a sealed state by closing the lid or shutter, a processing room for performing plasma processing may be formed therein. A stage for placing an object to be processed (e.g., a substrate) may be installed in the chamber.

The electrode part is configured to be applied with a high-frequency power for generating a plasma. The electrode part may be provided inside the chamber, may be provided outside the chamber with a dielectric member therebetween, or may be provided across inside and outside the chamber. A high-frequency power source may be electrically connected to the electrode part via a matcher. The electrode part may be fitted into an opening formed in the base. When a process gas is introduced into the chamber, and a high-frequency power is applied to the electrode part, a plasma is generated in the chamber. This allows an object to be processed on the stage to be plasma processed (e.g., etched).

The plasma sensor measures a measured value corresponding to an electric potential of the plasma. The plasma sensor may be, for example, a window-type probe fixed to the lid or to a sidewall of the chamber, but is not limited thereto. Only one plasma sensor may be provided, or a plurality of plasma sensors may be provided. The measured value may be, for example, a value of the voltage outputted by the window-type probe depending on the electric potential of the plasma, but is not limited thereto.

The threshold determination section determines a threshold, depending on the plasma processing condition. The plasma processing condition may be an information on plasma processing retrievable from a process recipe for plasma processing, such as the value of the high-frequency power applied to the electrode part. The plasma processing condition may change with deterioration of the apparatus. The plasma processing condition may be one specific condition, or may include a plurality of conditions. The threshold may be a threshold corresponding to the measured value of the plasma sensor. The threshold determination section may directly determine the threshold depending on the plasma processing condition, or may determine the threshold by substituting a parameter related to the plasma processing condition, as a variable, into a predetermined function. For example, a coefficient may be determined depending on the plasma processing condition, and a product obtained by multiplying this coefficient by a certain fixed value may be determined as the threshold.

The judgment section judges the presence or absence of abnormal discharge in the chamber, based on the measured value and the threshold. The judgment section may be configured to, for example, compare the measured value of the plasma sensor with the threshold determined depending on the plasma processing condition, and if the relationship between the two satisfies a predetermined condition, judge that an abnormal discharge is occurring in the chamber. As the predetermined condition, for example, the following can be used: that the measured value exceeds or falls below the threshold, or that the difference between the measured value and the predetermined value exceeds the threshold.

In the plasma processing apparatus of the present disclosure, as described above, the threshold used for judging the presence or absence of abnormal discharge is determined depending on the plasma processing condition. In other words, the threshold used for judgment is not a predetermined fixed value but a non-fixed value determined as appropriate depending on the plasma processing condition. Therefore, an appropriate threshold can be used for judgment on an abnormal discharge, depending on the plasma processing condition or on the state of plasma, and an erroneous judgment on the presence or absence of abnormal discharge can be avoided. According to the plasma processing apparatus of the present disclosure, it is possible to appropriately judge the presence or absence of abnormal discharge in the chamber.

The judgment section may judge that an abnormal discharge is occurring in the chamber when the difference between the measured value and the predetermined value exceeds the threshold. The predetermined value may be an average of the measured values (e.g., 0 V) measured while the plasma is in a stable state.

The plasma processing condition may include the value of the high-frequency power applied to the electrode part. The threshold determination section may determine the threshold, depending on at least the value of the high-frequency power. According to this configuration, the presence or absence of abnormal discharge in the chamber can be appropriately judged in response to the change in the value of the high-frequency power. The threshold determination section may determine the threshold, for example, according to a table designed depending on the value of the high-frequency power or according to an arbitrary function with its input being the value of the high-frequency power.

The threshold determination section may determine the threshold so as to be smaller as the value of the high-frequency power is higher. The judgment section may judge that an abnormal discharge is occurring in the chamber when the difference between the measured value and the predetermined value exceeds the threshold. Even without abnormal plasma discharge, the measured value can change due to minute fluctuations in the plasma. The amount of change in the measured value decreases as the value of the high-frequency power increases. This is because when the value of the high-frequency power increases, the density of electrons generated in the plasma increases, and the thickness of the sheath increases correspondingly, that is, the sheath capacitance decreases. Since the amount of change in the measured value is small, the difference between the measured value and the predetermined value is unlikely to exceed the threshold even though the threshold is set lower as the value of the high-frequency power is higher, and an erroneous detection of an abnormal discharge hardly occurs. Also, the amount of change in the measured value when an abnormal discharge actually occurs decreases similarly, as the value of the high-frequency power increases. Thus, when the threshold is too large, an abnormal discharge, if any, cannot be detected. Therefore, by determining the threshold so as to be smaller as the value of the high-frequency power is higher, it becomes possible to appropriately detect an abnormal discharge when it occurs.

The plasma processing condition may include the value of the pressure inside the chamber. The threshold determination section may determine the threshold, depending on at least the value of the pressure. According to this configuration, it is possible to appropriately judge the presence or absence of abnormal discharge in the chamber in response to the change in the value of the pressure inside the chamber. The threshold determination section may determine the threshold, for example, according to a table designed depending on the value of the pressure inside the chamber or according to an arbitrary function with its input being the value of the pressure inside the chamber.

The threshold determination section may determine the threshold so as to be larger as the value of the pressure is higher. The judgment section may judge that an abnormal discharge is occurring in the chamber when the difference between the measured value and the predetermined value exceeds the threshold. Even without abnormal plasma discharge, the measured value can change due to minute fluctuations in the plasma. The amount of change in the measured value increases as the value of the pressure in the chamber increases. This is because when the value of the pressure inside the chamber increases, the density of electrons generated in the plasma decreases, and the thickness of the sheath decreases correspondingly, that is, the sheath capacitance increases. Since the amount of change in the measured value is large, if without determining the threshold so as to be larger as the value of the pressure inside the chamber is higher, the difference between the measured value and the predetermined value tends to exceed the threshold, and an erroneous detection of an abnormal discharge tends to occur. Therefore, by determining the threshold so as to be larger as the value of the pressure inside the chamber is higher, it becomes possible to appropriately detect an abnormal discharge when it occurs.

The plasma processing condition may include a gas information on the composition or type of a process gas supplied into the chamber. The threshold determination section may determine the threshold, depending on at least the gas information. According to this configuration, it is possible to appropriately judge the presence or absence of abnormal discharge in the chamber in response to the change in the composition of the process gas. The threshold determination section may determine the threshold, for example, according to a table designed depending on the composition of the process gas.

The plasma processing condition may include a first plasma processing condition regarding a first plasma processing step, and a second plasma processing condition regarding a second plasma processing step performed after the first plasma processing step. The threshold determination section may determine a first threshold which is the threshold for judging the presence or absence of abnormal discharge during the first plasma processing step, depending on the first plasma processing condition, and determines a second threshold which is the threshold for judging the presence or absence of abnormal discharge during the second plasma processing step, depending on the second plasma processing condition. According to this configuration, when performing a plurality of plasma processing steps (i.e., first and second plasma processing steps), an appropriate threshold can be set for each plasma processing step. Therefore, in each of the first and second plasma processing steps, the presence or absence of abnormal discharge in the chamber can be appropriately judged. The first plasma processing condition and the second plasma processing condition may be different from each other.

The plasma processing condition may include a substrate information on a substrate to be plasma processed. The threshold determination section may determine the threshold, depending on at least the substrate information. According to this configuration, the presence or absence of abnormal discharge in the chamber can be appropriately judged depending on the change in the substrate information. The substrate information may be, for example, an information on the number, type, and/or area (area of the principal surface facing the plasma) of substrates to be plasma processed. The threshold determination section may determine the threshold, for example, according to a table designed depending on the total area of one or more substrates to be plasma processed (the sum of the areas of the principal surfaces of the substrates facing the plasma) or according to an arbitrary function with its input being the above total area. In the case where the judgment section judges that an abnormal discharge is occurring in the chamber when the difference between the measured value and the predetermined value exceeds the threshold, the threshold determination section may determine the threshold so as to be smaller as the total area of the one or more substrates is larger.

### Plasma Processing Method

A plasma processing method according to the present disclosure includes a plasma generation step, a measurement step, a threshold determination step, and a judgment step.

In the plasma generation step, a high-frequency power is applied to an electrode part, to generate a plasma in a chamber. An object to be processed (e.g., substrate) placed in the chamber may be plasma processed (e.g., etched) by the generated plasma.

In the measurement step, a measured value corresponding to an electric potential of the plasma is measured. For this measurement, a window-type probe fixed to the chamber may be used. The measured value may be, for example, the value of the voltage outputted from the window-type probe depending on the potential of the plasma, but is not limited thereto.

In the threshold determination step, a threshold is determined depending on the plasma processing condition. The plasma processing condition may be an information on plasma processing retrievable from a process recipe for plasma processing, such as the value of the high-frequency power applied to the electrode part. The plasma processing condition may change with deterioration of the apparatus. The plasma processing condition may be one specific condition, or may include a plurality of conditions. The threshold may be a threshold corresponding to the measured values of the plasma sensor. The threshold determination step may directly determine the threshold, depending on the plasma processing condition, or may determine the threshold by substituting a parameter related to the plasma processing condition into a predetermined function. For example, a coefficient may be determined depending on the plasma processing condition, and a product obtained by multiplying this coefficient by a certain fixed value may be determined as the threshold.

In the judgment step, the presence or absence of abnormal discharge in the chamber is judged, based on the measured value and the threshold. In the judgment step, for example, the measured value of the plasma sensor may be compared with the threshold determined depending on the plasma processing condition, and if the relationship between the two satisfies a predetermined condition, it may be judged that an abnormal discharge is occurring in the chamber. As the predetermined condition, for example, the following can be used: that the measured value exceeds or falls below the threshold, or that the difference between the measured value and the predetermined value exceeds the threshold.

In the plasma processing method of the present disclosure, as described above, the threshold used for judging the presence or absence of abnormal discharge is determined depending on the plasma processing condition. In other words, the threshold used for judgment is not a predetermined fixed value but a non-fixed value determined as appropriate depending on the plasma processing condition. Therefore, an appropriate threshold can be used for judgment on an abnormal discharge, depending on the plasma processing condition or on the state of plasma, and an erroneous judgment on the presence or absence of abnormal discharge can be avoided. According to the plasma processing method of the present disclosure, it is possible to appropriately judge the presence or absence of abnormal discharge in the chamber.

In the judgment step, it may be judged that an abnormal discharge is occurring in the chamber, when the difference between the measured value and the predetermined value exceeds the threshold. The predetermined value may be an average of the measured values (e.g., 0 V) measured while the plasma is in a stable state.

The plasma processing condition may include the value of the high-frequency power applied to the electrode part. In the threshold determination step, the threshold may be determined depending on at least the value of the high-frequency power. According to this configuration, the presence or absence of abnormal discharge in the chamber can be appropriately judged in response to the change in the value of the high-frequency power. In the threshold determination step, the threshold may be determined, for example, according to a table designed depending on the value of the high-frequency power or according to an arbitrary function with its input being the value of the high-frequency power.

In the threshold determination step, the threshold may be determined so as to be smaller as the value of the high-frequency power is higher. In the judgment step, it may be judged that an abnormal discharge is occurring in the chamber, when the difference between the measured value and the predetermined value exceeds the threshold. Even without abnormal plasma discharge, the measured value can change due to minute fluctuations in the plasma. The amount of change in the measured value decreases as the value of the high-frequency power increases. This is because, as described above, when the value of the high-frequency power increases, the sheath capacitance decreases. Since the amount of change in the measured value is small, the difference between the measured value and the predetermined value is unlikely to exceed the threshold even though the threshold is set lower as the value of the high-frequency power is higher, and an erroneous detection of an abnormal discharge hardly occurs. Also, the amount of change in the measured value when an abnormal discharge actually occurs decreases similarly, as the value of the high-frequency power increases. Thus, when the threshold is too large, an abnormal discharge, if any, cannot be detected. Therefore, by determining the threshold so as to be smaller as the value of the high-frequency power is higher, it becomes possible to appropriately detect an abnormal discharge when it occurs.

The plasma processing condition may include the value of the pressure inside the chamber. In the threshold determination step, the threshold may be determined depending on at least the value of the pressure. According to this configuration, it is possible to appropriately judge the presence or absence of abnormal discharge in the chamber in response to the change in the value of the pressure inside the chamber. In the threshold determination step, the threshold may be determined, for example, according to a table designed depending on the value of the pressure inside the chamber or according to an arbitrary function with its input being the value of the pressure inside the chamber.

In the threshold determination step, the threshold may be determined so as to be larger as the value of the pressure is higher. In the judgment step, it may be judged that an abnormal discharge is occurring in the chamber, when the difference between the measured value and the predetermined value exceeds the threshold. Even without abnormal plasma discharge, the measured value can change due to minute fluctuations in the plasma. The amount of change in the measured value increases as the value of the pressure in the chamber increases. This is because, as described above, when the value of the pressure inside the chamber increases, the sheath capacitance increases. Since the amount of change in the measured value is small, if without determining the threshold so as to be larger as the value of the pressure inside the chamber is higher, the difference between the measured value and the predetermined value tends to exceed the threshold, and an erroneous detection of an abnormal discharge tends to occur. Therefore, by determining the threshold so as to be larger as the value of the pressure inside the chamber is higher, it becomes possible to appropriately detect an abnormal discharge when it occurs.

The plasma processing condition may include a gas information on the composition or type of a process gas supplied into the chamber. In the threshold determination step, the threshold may be determined depending on at least the gas information. According to this configuration, it is possible to appropriately judge the presence or absence of abnormal discharge in the chamber in response to the change in the composition of the process gas. In the threshold determination step, the threshold may be determined, for example, according to a table designed depending on the composition of the process gas.

The plasma processing condition may include a first plasma processing condition regarding a first plasma processing step, and a second plasma processing condition regarding a second plasma processing step performed after the first plasma processing step. In the threshold determination step, a first threshold which is the threshold for judging the presence or absence of abnormal discharge during the first plasma processing step may be determined depending on the first plasma processing condition, and a second threshold which is the threshold for judging the presence or absence of abnormal discharge during the second plasma processing step may be determined depending on the second plasma processing condition. According to this configuration, when performing a plurality of plasma processing steps (i.e., first and second plasma processing steps), an appropriate threshold can be set for each plasma processing step. Therefore, in each of the first and second plasma processing steps, the presence or absence of abnormal discharge in the chamber can be appropriately judged. The first plasma processing condition and the second plasma processing condition may be different from each other.

The plasma processing condition may include a substrate information on a substrate to be plasma processed. In the threshold determination step, the threshold may be determined depending on at least the substrate information. According to this configuration, the presence or absence of abnormal discharge in the chamber can be appropriately judged depending on the change in the substrate information. The substrate information may be, for example, an information on the number, type, and/or area (area of the principal surface facing the plasma) of substrates to be plasma processed. In the threshold determination step, the threshold may be determined, for example, according to a table designed depending on the total area of one or more substrates to be plasma processed (the sum of the areas of the principal surfaces of the substrates facing the plasma) or according to an arbitrary function with its input being the above total area. In the case where in the judgment step, it is judged that an abnormal discharge is occurring in the chamber when the difference between the measured value and the predetermined value exceeds the threshold, in the threshold determining, the threshold may be determined so as to be smaller as the total area of the one or more substrates is larger.

As described above, according to the present disclosure, the presence or absence of abnormal discharge in the chamber can be appropriately judged by determining the threshold depending on the plasma processing condition.

In the following, examples of the plasma processing apparatus and method according to the present disclosure will be specifically described with reference to the drawings. The components and processes as described above can be applied to the components and processes of the below-described examples of the plasma processing apparatus and method. The components and processes of the below-described examples of the plasma processing apparatus and method can be modified based on the description above. The matters as described below may be applied to the above embodiments. Of the components and processes of the below-described examples of the plasma processing apparatus and method, the components and processes which are not essential to the plasma processing apparatus and method according to the present disclosure may be omitted. The figures below are schematic and not intended to accurately reflect the shape and the number of the actual members.

### Embodiment 1

Embodiment 1 of the present disclosure will be described.

### Plasma Processing Apparatus

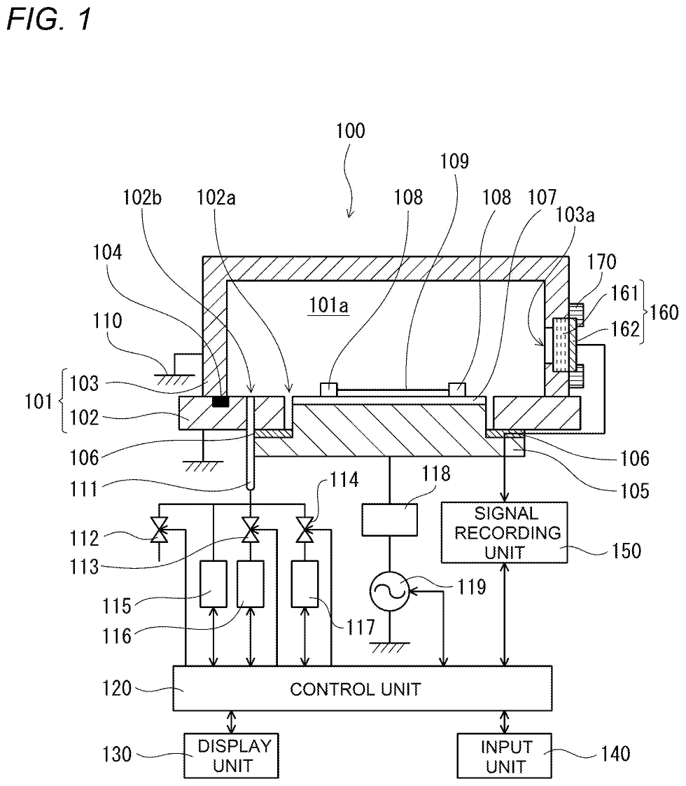

A plasma processing apparatus 100 of the present embodiment is a plasma cleaning apparatus, but is not limited thereto. As illustrated in FIGS. 1 to 3, the plasma processing apparatus 100 includes a chamber 101, an electrode part 105, a plasma sensor 160, and a control unit 120.

The chamber 101 includes a horizontal base 102 and a lid 103 that can be opened and closed. The lid 103 is provided so as to be vertically movable by means of a lifting means (not shown). When the lid 103 descends and comes in contact with the upper surface of the base 102, the chamber 101 is brought into a sealed state, forming a processing room 101a therein. At this time, a sealing member 104 is placed between the lid 103 and the base 102, by which the hermetically sealed state of the processing room 101a is secured. In the processing room 101a, a substrate 109 which is an object to be processed is plasma processed. The base 102 has an opening 102a formed in its center region, and a through-hole 102b formed around the opening 102a.

The electrode part 105 is fitted into the opening 102a of the base 102 with an insulating member 106 therebetween, so as to close the opening. The upper surface of the electrode part 105 is covered with an insulating layer 107. A guide member 108 for positioning the substrate 109 is disposed on the upper surface of the insulating layer 107.

A pipe conduit 111 is inserted into the through-hole 102b of the base 102. To the pipe conduit 111, a vent valve 112 , a gas supply valve 113 , a vacuum valve 114, and a vacuum gauge 115 are connected. To the gas supply valve 113 and the vacuum valve 114, a gas supply part 116 and a vacuum pump 117 are further connected, respectively. By turning the vacuum valve 114 to open and operating the vacuum pump 117, the gas in the processing room 101a is discharged, bringing the processing room 101a into a reduced pressure state. The degree of vacuum in the processing room 101a is measured by the vacuum gauge 115. On the other hand, when the gas supply valve 113 is turned to open, a process gas (gas for plasma generation) is supplied from the gas supply part 116 into the processing room 101a. The gas supply part 116 has a flow rate adjustment function incorporated therein, by which the flow rate of the gas for plasma generation supplied into the processing room 101a is adjusted. When the vent valve 112 is turned to open, air is supplied into the processing room 101a.

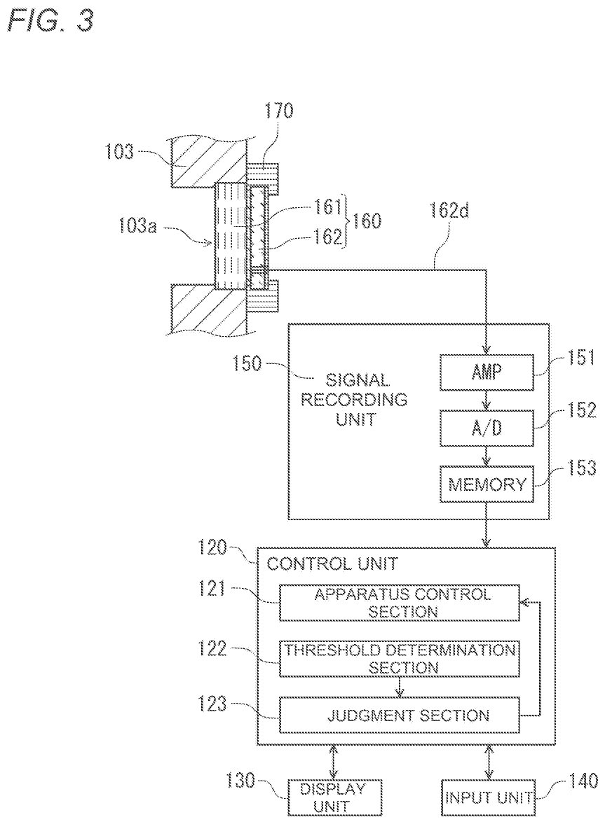

To the electrode part 105, a high-frequency power source 119 is electrically connected via a matcher 118. On the other hand, the lid 103 is grounded to a ground part 110. When a process gas is supplied into the processing room 101a, and the high-frequency power source 119 is operated, a high-frequency voltage is applied between the electrode part 105 and the lid 103. This causes a plasma to be generated in the processing room 101a. The matcher 118 performs matching of the impedance of a plasma discharge circuit (not shown) for generating a plasma to that of the high-frequency power source 119. The vent valve 112, the gas supply valve 113, the vacuum valve 114, the vacuum gauge 115, the gas supply part 116, the vacuum pump 117, and the high-frequency power source 119 are controlled by an apparatus control section 121 in the control unit 120 (see FIG. 3). That is, the apparatus control section 121 has a normal operation control function for executing a plasma processing operation.

The plasma sensor 160 measures a measured value MV corresponding to an electric potential of the plasma generated within the processing room 101a. The plasma sensor 160 is fixed so as to cover an opening 103a provided in the lid 103.

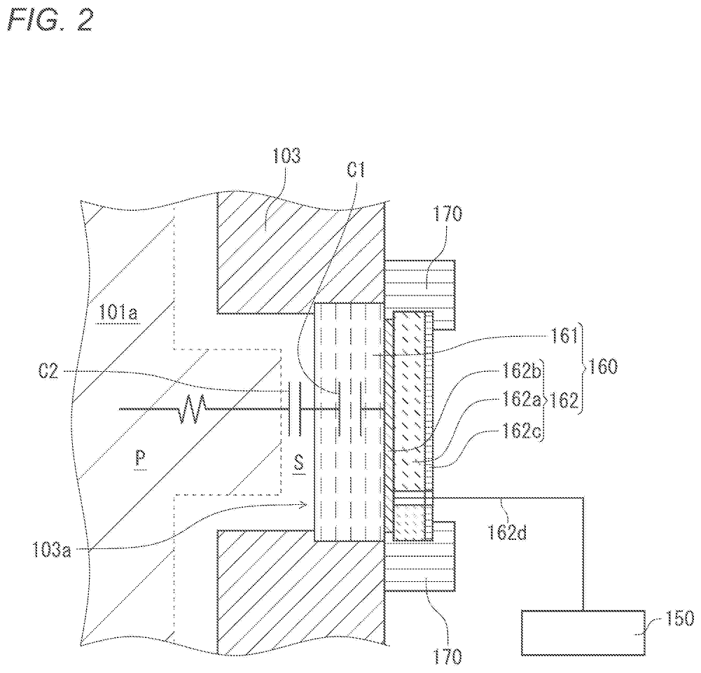

As illustrated in FIG. 2, the plasma sensor 160 includes a dielectric member 161 and a probe electrode unit 162. The plasma sensor 160 is fixed by a support member 170 on the outside of the lid 103 (on the side opposite to the processing room 101a). The dielectric member 161 has a flat plate shape, with one of its surfaces facing the processing room 101a, and the other surface facing a probe electrode 162b of the probe electrode unit 162. The material of the dielectric member 161 is, for example, an optically transparent glass. The material of the support member 170 may be any material that is electrically conductive, and is, for example, a metal.

The probe electrode unit 162 is constituted of the probe electrode 162b disposed on the dielectric member 161 side, a shield electrode 162c disposed so as to face the probe electrode 162b, and a glass plate 162a interposed therebetween. The probe electrode 162b and the dielectric member 161 are fixed by the support member 170 so as to be in close contact with each other. The probe electrode 162b is connected to a signal recording unit 150 via a detection lead wire 162d. The shield electrode 162c electrically shields the prove electrode unit 162 from outside. The probe electrode 162b and the shield electrode 162c are formed by, for example, coating the surface of the glass plate 162a with a transparent electrically conductive material of ITO (indium tin oxide). Therefore, through the plasma sensor 160, the inside of the processing room 101a can be visually recognized from outside.

When a plasma discharge occurs inside the processing room 101a, the probe electrode 162b is electrically connected to a generated plasma P via the dielectric member 161 and a sheath (space-charge layer) S formed at the interface between the plasma P and the dielectric member 161. That is, an electric circuit including series connected capacitor C1 formed by the dielectric member 161, capacitor C2 having a capacitance corresponding to that of the sheath S, and resistance due to the plasma P is formed, and at the probe electrode 162b, an electric potential is induced according to the state of the plasma P. In other words, the change in the electric potential at the probe electrode 162b represents the change in the state of the plasma P. The signal recording unit 150 receives the change in the electric potential at the probe electrode 162b via the detection lead wire 162d, and temporarily records it as a digital signal. On the other hand, the electric charge generated in the shield electrode 162c is released to the grounded lid 103 via the support member 170, and the noise is reduced.

As illustrated in FIG. 3, the signal recording unit 150 includes an amplifier (AMP 151), an A/D converter (A/D 152), and a memory 153. The AMP 151 amplifies the change in the electric potential (change in the measured value MV) at the probe electrode 162b transmitted via the detection lead wire 162d. The A/D 152 performs A/D conversion on the signal of the change in the electric potential amplified by the AMP 151. The A/D-converted digital signal indicating the change in the electric potential is temporarily recorded in the memory 153 in accordance with the write control of the control unit 120. The digital signal recorded temporarily in the memory 153 is erased in accordance with a clear command from the control unit 120.

The control unit 120 includes the apparatus control section 121, a threshold determination section 122, and a judgment section 123. The control unit 120 includes an arithmetic device and a storage device in which a program executable by the arithmetic device is stored. This program is executed by the arithmetic device, through which the control unit 120 can function as a functional unit of each of these sections.

The apparatus control section 121 has, in addition to the control functions for normal operation as described above, a retry function for performing a retry processing when a plasma discharge fails to start normally, and a cumulative plasma processing function for performing a cumulative plasma processing when an abnormal discharge is detected after plasma processing has started normally. The apparatus control section 121 may perform, for example, a cumulative plasma processing by which whether the plasma processing to the same substrate 109 is resumed or not is determined when an abnormal discharge is detected by the judgment section 123.

The threshold determination section 122 determines a threshold TH depending on the plasma processing condition. The plasma processing condition of the present embodiment includes a value of the high-frequency power applied to the electrode part 105. Therefore, the threshold determination section 122 of the present embodiment determines the threshold TH depending on at least the value of the high-frequency power applied to the electrode part 105. The value of the high-frequency power is retrievable from the process recipe. The threshold TH is a threshold corresponding to the measured value MV of the plasma sensor 160, and when the difference (e.g., the absolute value of the measured value MV) between the measured value MV and a predetermined value (e.g., 0 V) exceeds the threshold TH, the judgment section 123 judges that an abnormal discharge is occurring in the chamber 101.

The threshold determination section 122 determines the threshold TH so as to be smaller as the value of the high-frequency power applied to the electrode part 105 is higher. As a specific example, given that 0<TH11<TH12<TH13, the threshold determination section 122 may determine the threshold TH as TH13 when the value of the high-frequency power is 0 W or more and less than 100 W, may determine the threshold TH as TH12 when the value of the high-frequency power is 100 W or more and less than 200 W, and may determine the threshold TH as TH11 when the value of the high-frequency power is 200 W or more and less than 300 W. With regard to the range of the value of the high-frequency power of 300 W or more, the threshold TH may be determined for each increment of 100 W.

The judgment section 123 judges the presence or absence of abnormal discharge in the chamber 101, based on the measured value MV of the plasma sensor 160 and the threshold TH. The judgment section 123 reads the information on the measured value MV from the memory 153 of the signal recording unit 150. As described above, the judgment section 123 judges that an abnormal discharge is occurring in the chamber 101 when the difference (e.g., the absolute value of the measured value MV) between the measured value MV and the predetermined value (e.g., 0 V) exceeds the threshold TH. A signal regarding the judgment result of the judgment section 123 is sent to the apparatus control section 121.

To the control unit 120, a display unit 130, an input unit 140, and the signal recording unit 150 are connected. The display unit 130 displays the judgment result on the presence or absence of abnormal discharge made by the judgment section 123, and the like. To the input unit 140, a process recipe including an information on the plasma processing condition is inputted. As described above, the signal recording unit 150 records, as a digital signal, the change in the electric potential (change in the measured value MV) measured by the plasma sensor 160.

### Plasma Processing Method

The plasma processing method of the present embodiment can be executed in the plasma processing apparatus 100 as described above, but may be executed in other types of plasma processing apparatus or plasma processing system. The plasma processing method includes a plasma generation step, a measurement step, a threshold determination step, and a judgment step.

In the plasma generation step, a process gas is supplied into the processing chamber 101a in a reduced pressure atmosphere and applying a high-frequency power to the electrode part 105, thereby to generate a plasma in the processing room 101a.

In the measurement process, the value MV corresponding to the plasma potential is measured. For this measurement, the plasma sensor 160 described above can be used.

In the threshold determination step, the threshold TH is determined depending on the plasma processing condition. The plasma processing condition of the present embodiment includes a value of the high-frequency power applied to the electrode part 105. Therefore, in the threshold determination step of the present embodiment, the threshold TH is determined depending on at least the value of the high-frequency power applied to the electrode part 105. The value of the high-frequency power is retrievable from the process recipe. The threshold TH is a threshold corresponding to the measured value MV of the plasma sensor 160.

In the threshold determination step, the threshold TH is determined so as to be smaller as the value of the high-frequency power applied to the electrode part 105 is higher. As a specific example, given that 0<TH11<TH12<TH13, in the threshold determination step, the threshold TH may be determined as TH13 when the value of the high-frequency power is 0 W or more and less than 100 W, the threshold TH may be determined as TH12 when the value of the high-frequency power is 100 W or more and less than 200 W, and the threshold TH may be determined as TH11 when the value of the high-frequency power is 200 W or more and less than 300 W. With regard to the range of the value of the high-frequency power of 300 W or more, the threshold TH may be determined for each increment of 100 W.

In the judgment step, the presence or absence of abnormal discharge in the chamber 101 is judged, based on the measured value MV of the plasma sensor 160 and the threshold TH. In the judgment step, it is determined that an abnormal discharge is occurring in the chamber 101 when the difference (e.g., the absolute value of the measured value MV) between the measured value MV and a predetermined value (e.g., 0 V) exceeds the threshold TH.

### Embodiment 2

Embodiment 2 of the present disclosure will be described. The present embodiment differs from the above Embodiment 1 in the method of determining the threshold TH. In the following, the difference from above Embodiment 1 will be mainly described.

### Plasma Processing Apparatus

The plasma processing condition of the present embodiment includes a value of the pressure inside the chamber 101. Therefore, the threshold determination section 122 of the present embodiment determines the threshold TH, depending on at least the value of the pressure inside the chamber 101. The value of the pressure inside the chamber 101 can be measured by the vacuum gauge 115.

The threshold determination section 122 determines the threshold TH so as to be larger as the pressure inside the chamber 101 is higher. As a specific example, given that 0<TH21<TH22<TH23, the threshold determination section 122 may determine the threshold TH as TH21 when the value of the pressure is 0 Pa or more and less than 1 Pa, may determine the threshold TH as TH22 when the value of the pressure is 1 Pa or more and less than 10 Pa, and may determine the threshold TH as TH23 when the value of the pressure is 10 Pa or more and less than 20 Pa. With regard to the range of the value of the pressure of 20 Pa or more, the threshold TH may be determined for each increment of 10 Pa.

### Plasma Processing Method

The plasma processing condition of the present embodiment includes a value of the pressure inside the chamber 101. Therefore, in the threshold determination step of the present embodiment, the threshold TH is determined depending on at least the value of the pressure inside the chamber 101. The pressure value inside the chamber 101 can be measured by the vacuum gauge 115.

In the threshold determination step, the threshold TH is determined so as to be larger as the pressure inside the chamber 101 is higher. As a specific example, given that 0<TH21<TH22<TH23, in the threshold determination step, the threshold TH may be determined as TH21 when the value of the pressure is 0 Pa or more and less than 1 Pa, the threshold TH may be determined as TH22 when the value of the pressure is 1 Pa or more and less than 10 Pa, and the threshold TH may be determined as TH23 when the value of the pressure is 10 Pa or more and less than 20 Pa. With regard to the range of the value of the pressure of 20 Pa or more, the threshold TH may be determined for each increment of 10 Pa.

### Embodiment 3

Embodiment 3 of the present disclosure will be described. The present embodiment differs from the above Embodiment 1 in the method of determining the threshold TH. In the following, the difference from above Embodiment 1 will be mainly described.

### Plasma Processing Apparatus

The plasma processing condition of the present embodiment includes a gas information on the composition of a process gas supplied into the chamber 101. Therefore, the threshold determination section 122 of the present embodiment may determine the threshold TH, depending on at least the gas information. The gas information is retrievable from the process recipe. The threshold determination section 122 may determine the threshold TH by using a table that defines the threshold TH unique to each process gas.

### Plasma Processing Method

The plasma processing condition of the present embodiment includes a gas information on the composition of a process gas supplied into the chamber 101. Therefore, in the threshold determination step of the present embodiment, the threshold TH is determined depending on at least the gas information. The gas information is retrievable from the process recipe. In the threshold determination step, the threshold TH may be determined by using a table that defines the threshold TH unique to each process gas.

### Embodiment 4

Embodiment 4 of the present disclosure will be described. The present embodiment differs from the above Embodiment 1 in the method of determining the threshold TH. In the following, the difference from above Embodiment 1 will be mainly described.

### Plasma Processing Apparatus

The plasma processing condition of the present embodiment includes a substrate information on the substrate 109 to be plasma processed. Therefore, the threshold determination section 122 of the present embodiment may determine the threshold TH, depending on at least the substrate information. The substrate information is retrievable from the process recipe.

The threshold determination section 122 determines the threshold TH so as to be smaller as the number of the substrates 109 to be plasma processed is greater. As a specific example, given that 0<TH41<TH42<TH43, the threshold determination section 122 may determine the threshold TH as TH43 when the number of the substrates 109 is one, may determine the threshold TH as TH42 when the number of the substrates 109 is two, and may determine the threshold TH as TH41 when the number of the substrates 109 is three. With regard to the range of the number of the substrates 109 of four or greater, the threshold TH may be determined for each increment of one in the number of substrates.

### Plasma Processing Method

The plasma processing condition of the present embodiment includes a substrate information on the substrate 109 to be plasma processed. Therefore, in the threshold determination step of the present embodiment, the threshold TH may be determined depending on at least the substrate information. The substrate information is retrievable from the process recipe.

In the threshold determination step, the threshold TH is determined so as to be smaller as the number of the substrates 109 to be plasma processed is greater. As a specific example, given that 0<TH41<TH42<TH43, in the threshold determination step, the threshold TH may be determined as TH43 when the number of the substrates 109 is one, the threshold TH may be determined as TH42 when the number of the substrates 109 is two, and the threshold TH may be determined as TH41 when the number of the substrates 109 is three. With regard to the range of the number of the substrates 109 of four or greater, the threshold TH may be determined for each increment of one in the number of substrates.

### Embodiment 5

Embodiment 5 of the present disclosure will be described. The present embodiment differs from the above Embodiment 1 in the method of determining the threshold TH. In the following, the difference from above Embodiment 1 will be mainly described.

### Plasma Processing Apparatus

The plasma processing condition of the present embodiment includes a first plasma processing condition regarding a first plasma processing step, and a second plasma processing condition regarding a second plasma processing step performed after the first plasma processing step. The first plasma processing condition and the second plasma processing condition each include, for example, a value of the flow rate of the process gas, a value of the pressure inside the chamber 101, and a value of the high-frequency power applied to the electrode part 105.

The threshold determination section 122 of the present embodiment determines a first threshold TH51 which is the threshold TH for judging the presence or absence of abnormal discharge during the first plasma processing step, depending on the first plasma processing condition, and determines a second threshold TH52 which is the threshold TH for judging the presence or absence of abnormal discharge during the second plasma processing step, depending on the second plasma processing condition. For example, the threshold determination section 122 may determine a plurality of coefficients, depending on the values included in the plasma processing condition, and then, may determine the first threshold TH51 as a product obtained by multiplying the plurality of coefficients by a certain fixed value. The same applies to the second threshold TH52.

### Plasma Processing Method

The plasma processing condition of the present embodiment includes a first plasma processing condition regarding a first plasma processing step, and a second plasma processing condition regarding a second plasma processing step performed after the first plasma processing step. The first plasma processing condition and the second plasma processing condition each include, for example, the value of the flow rate of the process gas, the value of the pressure inside the chamber 101, and the value of the high-frequency power applied to the electrode part 105.

In the threshold determination step of the present embodiment, a first threshold TH51 which is the threshold TH for judging the presence or absence of abnormal discharge during the first plasma processing step is determined depending on the first plasma processing condition, and a second threshold TH52 which is the threshold TH for judging the presence or absence of abnormal discharge during the second plasma processing step is determined depending on the second plasma processing condition. For example, in the threshold determination step, a plurality of coefficients may be determined depending on the values included in the plasma processing condition, and then, the first threshold TH51 may be determined as a product obtained by multiplying the plurality of coefficients by a certain fixed value. The same applies to the second threshold TH52.

### Supplementary Note

The following techniques are disclosed by the foregoing description of embodiments.

(Technique 1)

A plasma processing apparatus, comprising:

a chamber in which plasma processing is performed;

an electrode part configured to be applied with a high-frequency power for generating a plasma in the chamber;

a plasma sensor for measuring a measured value corresponding to an electric potential of the plasma;

a threshold determination section for determining a threshold, depending on a plasma processing condition; and

a judgment section for judging presence or absence of abnormal discharge in the chamber, based on the measured value and the threshold.

(Technique 2)

The plasma processing apparatus according to technique 1, wherein the judgment section judges that an abnormal discharge is occurring in the chamber when a difference between the measured value and a predetermined value exceeds the threshold.

(Technique 3)

The plasma processing apparatus according to technique 1 or 2, wherein

the plasma processing condition includes a value of the high-frequency power applied to the electrode part, and

the threshold determination section determines the threshold, depending on at least the value of the high-frequency power.

(Technique 4)

The plasma processing apparatus according to technique 3, wherein the threshold determination section determines the threshold so as to be smaller as the value of the high-frequency power is higher.

(Technique 5)

The plasma processing apparatus according to any one of techniques 1 to 4, wherein

the plasma processing condition includes a value of a pressure inside the chamber, and

the threshold determination section determines the threshold, depending on at least the value of the pressure.

(Technique 6)

The plasma processing apparatus according to technique 5, wherein the threshold determination section determines the threshold so as to be larger as the value of the pressure is higher.

(Technique 7)

The plasma processing apparatus according to any one of techniques 1 to 6, wherein

the plasma processing condition includes a gas information on a composition of a process gas supplied into the chamber, and the threshold determination section determines the threshold, depending on at least the gas information.

(Technique 8)

The plasma processing apparatus according to any one of techniques 1 to 7, wherein

the plasma processing condition includes a first plasma processing condition regarding a first plasma processing step, and a second plasma processing condition regarding a second plasma processing step performed after the first plasma processing step, and the threshold determination section determines a first threshold which is the threshold for judging presence or absence of abnormal discharge during the first plasma processing step, depending on the first plasma processing condition, and determines a second threshold which is the threshold for judging presence or absence of abnormal discharge during the second plasma processing step, depending on the second plasma processing condition.

(Technique 9)

The plasma processing apparatus according to any one of techniques 1 to 8, wherein

the plasma processing condition includes a substrate information on a substrate to be plasma processed, and the threshold determination section determines the threshold, depending on at least the substrate information.

(Technique 10)

A plasma processing method, comprising:

a plasma generation step of applying a high-frequency power to an electrode part, to generate a plasma in a chamber;

a measurement step of measuring a measured value corresponding to an electric potential of the plasma;

a threshold determination step of determining a threshold, depending on a plasma processing condition; and a judgment step of judging presence or absence of abnormal discharge in the chamber, based on the measured value and the threshold.

(Technique 11)

The plasma processing method according to technique 10, wherein in the judgment step, it is judged that an abnormal discharge is occurring in the chamber when a difference between the measured value and a predetermined value exceeds the threshold.

(Technique 12)

The plasma processing method according to technique 10 or 11, wherein

the plasma processing condition includes a value of the high-frequency power applied to the electrode part, and in the threshold determination step, the threshold is determined depending on at least the value of the high-frequency power.

(Technique 13)

The plasma processing method according to technique 12, wherein in the threshold determination step, the threshold is determined so as to be smaller as the value of the high-frequency power is higher.

(Technique 14)

The plasma processing method according to any one of techniques 10 to 13, wherein

the plasma processing condition includes a value of a pressure inside the chamber, and in the threshold determination step, the threshold is determined depending on at least the value of the pressure.

(Technique 15)

The plasma processing method according to technique 14, wherein in the threshold determination step, the threshold is determined so as to be larger as the value of the pressure is higher.

(Technique 16)

The plasma processing method according to any one of techniques 10 to 15, wherein

the plasma processing condition includes a gas information on a composition of a process gas supplied into the chamber, and in the threshold determination step, the threshold is determined depending on at least the gas information.

(Technique 17)

The plasma processing method according to any one of techniques 10 to 16, wherein

the plasma processing condition includes a first plasma processing condition regarding a first plasma processing step, and a second plasma processing condition regarding a second plasma processing step performed after the first plasma processing step, and

in the threshold determination step, a first threshold which is the threshold for judging presence or absence of abnormal discharge during the first plasma processing step is determined depending on the first plasma processing condition, and a second threshold which is the threshold for judging presence or absence of abnormal discharge during the second plasma processing step is determined depending on the second plasma processing condition.

(Technique 18)

The plasma processing method according to any one of techniques 10 to 17, wherein

the plasma processing condition includes a substrate information on a substrate to be plasma processed, and

in the threshold determination step, the threshold is determined depending on at least the substrate information.

The present disclosure is applicable to a plasma processing apparatus and a plasma processing method.

### REFERENCE NUMERALS

100: plasma processing apparatus
101: chamber
   101a: processing room
   102: base
      102a: opening
      102b: through-hole
   103: lid
      103a: opening
104: sealing member
105: electrode part
106: insulating member
107: insulating layer
108: guide member
109: substrate (object to be processed)
110: ground part
111: pipe conduit
112: vent valve
113: gas supply valve
114: vacuum valve
115: vacuum gauge
116: gas supply part
117: vacuum pump
118: matcher
119: high-frequency power source
120: control unit
121: apparatus control section
122: threshold determination section
123: judgment section

130: display unit

140: input unit

150: signal recording unit
151: AMP
152: A/D
153: memory

160: plasma sensor
161: dielectric member
162: probe electrode unit
   162a: glass plate
   162b: probe electrode
   162c: shield electrode
   162d: detection lead wire
170: support member

C1, C2: capacitor

MV: measured value

P: plasma

S: sheath

TH: threshold

TH51: first threshold

TH52: second threshold

What is claimed is:

1. A plasma processing apparatus, comprising:
a chamber in which plasma processing is performed;
an electrode part configured to be applied with a high-frequency power for generating a plasma in the chamber;
a plasma sensor for measuring a measured value corresponding to an electric potential of the plasma;
a threshold determination section for determining a threshold, depending on a plasma processing condition; and
a judgment section for judging presence or absence of abnormal discharge in the chamber, based on the measured value and the threshold.

2. The plasma processing apparatus according to claim 1, wherein the judgment section judges that an abnormal discharge is occurring in the chamber when a difference between the measured value and a predetermined value exceeds the threshold.

3. The plasma processing apparatus according to claim 1, wherein
the plasma processing condition includes a value of the high-frequency power applied to the electrode part, and
the threshold determination section determines the threshold, depending on at least the value of the high-frequency power.

4. The plasma processing apparatus according to claim 3, wherein the threshold determination section determines the threshold so as to be smaller as the value of the high-frequency power is higher.

5. The plasma processing apparatus according to claim 1, wherein
the plasma processing condition includes a value of a pressure inside the chamber, and
the threshold determination section determines the threshold, depending on at least the value of the pressure.

6. The plasma processing apparatus according to claim 5, wherein the threshold determination section determines the threshold so as to be larger as the value of the pressure is higher.

7. The plasma processing apparatus according to claim 1, wherein
the plasma processing condition includes a gas information on a composition of a process gas supplied into the chamber, and
the threshold determination section determines the threshold, depending on at least the gas information.

8. The plasma processing apparatus according to claim 1, wherein
the plasma processing condition includes a first plasma processing condition regarding a first plasma processing step, and a second plasma processing condition regarding a second plasma processing step performed after the first plasma processing step, and
the threshold determination section determines a first threshold which is the threshold for judging presence or absence of abnormal discharge during the first plasma processing step, depending on the first plasma processing condition, and determines a second threshold which is the threshold for judging presence or absence of abnormal discharge during the second plasma processing step, depending on the second plasma processing condition.

9. The plasma processing apparatus according to claim 1, wherein
the plasma processing condition includes a substrate information on a substrate to be plasma processed, and
the threshold determination section determines the threshold, depending on at least the substrate information.

10. A plasma processing method, comprising:
a plasma generation step of applying a high-frequency power to an electrode part, to generate a plasma in a chamber;
a measurement step of measuring a measured value corresponding to an electric potential of the plasma;
a threshold determination step of determining a threshold, depending on a plasma processing condition; and
a judgment step of judging presence or absence of abnormal discharge in the chamber, based on the measured value and the threshold.

11. The plasma processing method according to claim 10, wherein in the judgment step, it is judged that an abnormal discharge is occurring in the chamber when a difference between the measured value and a predetermined value exceeds the threshold.

12. The plasma processing method according to claim 10, wherein
the plasma processing condition includes a value of the high-frequency power applied to the electrode part, and
in the threshold determination step, the threshold is determined depending on at least the value of the high-frequency power.

13. The plasma processing method according to claim 12, wherein in the threshold determination step, the threshold is determined so as to be smaller as the value of the high-frequency power is higher.

14. The plasma processing method according to claim 10, wherein
the plasma processing condition includes a value of a pressure inside the chamber, and
in the threshold determination step, the threshold is determined depending on at least the value of the pressure.

15. The plasma processing method according to claim 14, wherein in the threshold determination step, the threshold is determined so as to be larger as the value of the pressure is higher.

16. The plasma processing method according to claim 10, wherein
the plasma processing condition includes a gas information on a composition of a process gas supplied into the chamber, and
in the threshold determination step, the threshold is determined depending on at least the gas information.

17. The plasma processing method according to claim 10, wherein
the plasma processing condition includes a first plasma processing condition regarding a first plasma processing step, and a second plasma processing condition regarding a second plasma processing step performed after the first plasma processing step, and
in the threshold determination step, a first threshold which is the threshold for judging presence or absence of abnormal discharge during the first plasma processing step is determined depending on the first plasma processing condition, and a second threshold which is the threshold for judging presence or absence of abnormal discharge during the second plasma processing step is determined depending on the second plasma processing condition.

18. The plasma processing method according to claim 10, wherein
the plasma processing condition includes a substrate information on a substrate to be plasma processed, and
in the threshold determination step, the threshold is determined depending on at least the substrate information.
